(19) United States
(12) Patent Application Publication
(10) Pub. No.: US 2013/0239893 A1
(43) Pub. Date: Sep. 19, 2013

(54) STABILIZATION METHOD OF FILM FORMING APPARATUS AND FILM FORMING APPARATUS

(71) Applicant: TOKYO ELECTRON LIMITED, Tokyo (JP)

(72) Inventors: Keisuke SUZUKI, Nirasaki City (JP); Kentaro Kadonaga, Nirasaki City (JP)

(73) Assignee: TOKYO ELECTRON LIMITED, Tokyo (JP)

(21) Appl. No.: 13/800,208

(22) Filed: Mar. 13, 2013

(30) Foreign Application Priority Data
Mar. 14, 2012 (JP) 2012-057718

(51) Int. Cl. H01L 21/02

(52) U.S. Cl. CPC H01L 21/02104
USPC 118/724; 432/1

(57) ABSTRACT

A method for stabilizing a film forming apparatus, which can selectively perform a boron-containing nitride film forming process or a non-boron-containing nitride film forming process on at least one target object to be processed in a vacuum-evacuable processing chamber, the method includes performing a heat stabilization process to heat the interior of the processing chamber under an oxygen-containing gas atmosphere, between the boron-containing nitride film forming process and the non-boron-containing nitride film forming process when the non-boron-containing nitride film forming process is performed after the boron-containing nitride film forming process.

### CROSS-REFERENCE TO RELATED APPLICATION

This application claims the benefit of Japanese Patent Application No. 2012-057718, filed on Mar. 14, 2012, in the Japan Patent Office, the disclosure of which is incorporated herein in its entirety by reference.

### TECHNICAL FIELD

The present disclosure relates to a stabilization method of a film forming apparatus, which is configured to form a thin film on a target object such as a semiconductor wafer, and a film forming apparatus.

### BACKGROUND

In manufacturing semiconductor integrated circuits, a semiconductor wafer made of a silicon substrate is generally subjected to various processes, e.g., film formation, etching, oxidation, diffusion, modification and native oxide film removal. These processes are carried out by a single wafer processing apparatus which processes wafers one-by-one or by a batch type processing apparatus which processes a plurality of wafers simultaneously. When performing the processes using a vertical batch type processing apparatus, for example, a plurality of wafers are first loaded from a cassette accommodating the wafers therein, e.g., twenty five wafers, into a vertical wafer boat, and then supported by the boat in multi-levels.

The number of wafers loaded into the wafer boat may depend on, for example, the size of the wafers, but about thirty to one hundred and fifty wafers may be loaded into the wafer boat. The wafer boat is loaded into a gas-evacuable processing chamber from the bottom side, and then the interior of the processing chamber is kept airtight. Thereafter, a predetermined heat treatment is performed while controlling various process conditions such as flow rates of processing gases, a process pressure and a process temperature.

Among several factors affecting characteristics of semiconductor integrated circuits, it is important to improve the characteristics of insulating films in semiconductor integrated circuits. Silicon nitride films tend to be used as the insulating films in semiconductor integrated circuits instead of silicon oxide films due to their good insulation property. In particular, with an increase of demand for higher miniaturization and higher integration, silicon nitride films doped with impurities such as boron (B) are recently being used because they have lower dielectric constants (low-k) to be formed. For example, sealing films for protecting gate electrodes are formed in a semiconductor device such as a dynamic random-access memory (DRAM), and studies are now being made to form the sealing films with impurity-containing silicon nitride films.

In practical semiconductor device manufacturing processes, it is required to form various silicon nitride films including pure silicon nitride films and impurity-containing silicon nitride films. In some cases, pure silicon nitride (SiN) films containing no impurities and silicon nitride films containing impurities such as boron or carbon may be formed by using a single semiconductor manufacturing apparatus, for example.

In the above-described cases, the pure silicon nitride films containing no impurities and the silicon nitride films containing impurities are selectively formed as needed in the single semiconductor manufacturing apparatus.

However, if a silicon nitride film that does not contain boron is formed right after a silicon nitride film containing boron is formed, a problem may occur in that the film thickness of the silicon nitride film that does not contain boron partially increases, which deteriorates in-plane uniformity of the film thickness, or that boron atoms attached to the inner wall of the processing chamber enter into the silicon nitride film that does not contain boron.

Hereinafter, deterioration of in-plan uniformity of the film thickness will be described with reference to FIG. 6. FIG. 6 illustrates a graph for explaining an effect of a boron-containing silicon nitride film. Shown in FIG. 6 are film forming rates and in-plane uniformities of the film thickness when performing film forming processes by using a vertical film forming apparatus capable of simultaneously processing a plurality of semiconductor wafers. In the example of FIG. 6, a reference run was firstly performed to form a pure silicon nitride (SiN) film under a state where the inner wall of the film forming apparatus is not contaminated with boron, and then semiconductor wafers were replaced and a SiBN film was formed as a boron-containing silicon nitride film. Thereafter, a first run, a second run and a third run were sequentially performed to form pure silicon nitride (SiN) films. Semiconductor wafers were replaced for each of the runs (film forming processes).

In FIG. 6, black circles “” denote the film forming rates and white circles “o” denote the in-plane uniformities of the film thickness, while the left-side vertical axis and the right-side vertical axis are scaled by the film forming rates and the in-plane uniformities of the film thickness, respectively. Also, the wafer boat supporting the semiconductor wafers is vertically divided into five regions. In FIG. 6, the five regions are denoted by five numbers in such a manner that the top most region, the center region and the bottom most region are denoted by “1”, “3” and “5”, respectively. Further, “T”, “C” and “B” shown in FIG. 6 denote “top”, “center” and “bottom”, respectively.

As clearly shown in FIG. 6, the interior of the processing chamber gets unstabilized by the boron-containing SiBN film forming process, and thus the SiN films generated at the first and the second run, which were performed after the SiBN film forming process, have film thicknesses thicker than the film thickness of the SiN film generated at the reference run. In particular, it can be known from FIG. 6 that the film thicknesses in the top most region 1 increase remarkably at the first and the second run and that the in-plane uniformities at the first and the second run deteriorate. It can be also known from FIG. 6 that the film forming rate and the in-plane uniformity at the third run are almost the same as those at the reference run and that the processing chamber gets stabilized at the third run to improve the reproducibility. The reason for the above-described remarkable fluctuation in film thickness and deterioration of the in-plane uniformity in film thickness at the first and the second run is thought that boron has a catalytic action for activating silicon.

In order to prevent the above-described problems, the inner wall of the processing chamber may be covered with a dielectric insulating film after forming the boron-containing nitride film. However, such countermeasure has a drawback in that an additional film forming process is required.

### SUMMARY

Some embodiments of the present disclosure provide a stabilization method of a film forming apparatus and a film forming apparatus, in which a processing chamber gets stabilized after a boron-containing nitride film forming process to thereby prevent boron from exerting bad influence on a subsequent non-boron-containing nitride film forming process and improve reproducibility of the film forming processes.

The present inventors studied an impurity-containing silicon nitride film forming process. Throughout the study, the present inventors have come to know that boron atoms have a catalytic action, which activates silicon and facilitates nitridation of silicon to thereby increase the film thickness of the silicon nitride film, and that this catalytic action can be effectively suppressed by heating the interior of the processing chamber under an oxygen-containing atmosphere. The present disclosure is derived from the above-described knowledge.

According to a first aspect of the present disclosure, there is provided a method for stabilizing a film forming apparatus which can selectively perform a boron-containing nitride film forming process or a non-boron-containing nitride film forming process on at least one target object to be processed in a vacuum-evacuable processing chamber, the method includes performing a heat stabilization process to heat the interior of the processing chamber under an oxygen-containing gas atmosphere, between the boron-containing nitride film forming process and the non-boron-containing nitride film forming process when the non-boron-containing nitride film forming process is performed after the boron-containing nitride film forming process.

According to a second aspect of the present disclosure, there is provided a film forming apparatus configured to form thin films on one or more target objects to be processed. The apparatus includes a vertical and cylindrical processing chamber configured to be capable of evacuating gas; a holding unit configured to hold the target object in multi-levels and to be inserted into and ejected from the interior of the processing chamber; a heating unit installed around the outer periphery of the processing chamber; a gas supply system configured to supply a plurality of gases into the processing chamber; and a control unit configured to control the film forming apparatus to perform the stabilization method of the first aspect of the present disclosure.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a vertical sectional view of a film forming apparatus in accordance with an embodiment of the present disclosure.

FIG. 2 is a transverse sectional view of the film forming apparatus in accordance with the embodiment of the present disclosure.

FIGS. 3A and 3B are timing charts illustrating supply timings of various gases.

FIG. 4 is a flowchart for explaining a method stabilizing a film forming apparatus in accordance with the embodiment of the present disclosure, in which a series of processes performed in the film forming apparatus is illustrated.

FIGS. 5A and 5B are graphs illustrating evaluation results of the stabilization method of the film forming apparatus in accordance with the embodiment of the present disclosure.

FIG. 6 is a graph for explaining an effect of a boron-containing silicon nitride film.

### DETAILED DESCRIPTION

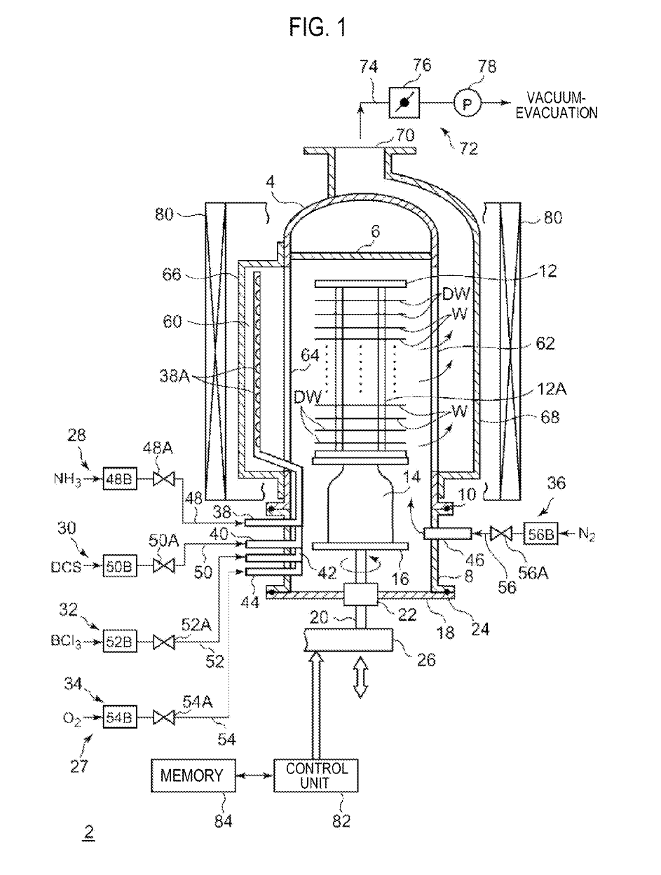

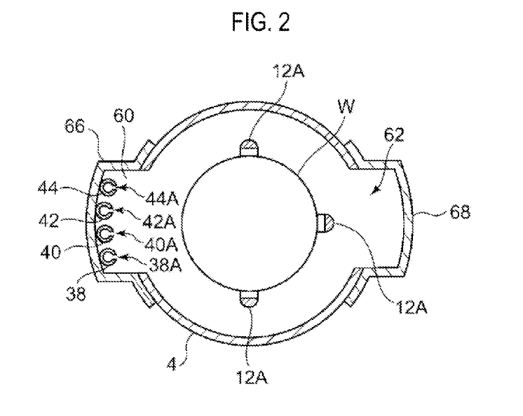

Hereinafter, embodiment(s) of a stabilization method of a film forming apparatus and a film forming apparatus according to the present disclosure will be described in detail with reference to the drawings. In addition, throughout the drawings, like reference numerals are used to designate like elements. FIG. 1 is a vertical sectional view of a film forming apparatus 2 in accordance with an embodiment of the present disclosure. FIG. 2 is a transverse sectional view of the film forming apparatus in accordance with the embodiment of the present disclosure. In FIG. 2, a heating unit is omitted. The following description will be made with an example using dichlorosilane (DCS) gas as a silane gas, using ammonia (NH₃) as a nitride gas, using boron trichloride (BCl₃) gas as a boron-containing gas and using oxygen (O₂) gas as an oxygen-containing gas to thereby form a SiBN film as a boron-containing nitride film and a SiN (silicon nitride) film as a non-boron-containing nitride film.

As shown in FIGS. 1 and 2, the film forming apparatus 2 includes a vertical and cylindrical processing chamber 4 having a ceiling and an opening at the bottom end thereof. The entire body of the processing chamber 4 is made of, for example, quartz and a ceiling plate 6 made of quartz is air-tightly provided in the ceiling of the processing chamber 4. Further, a cylindrical manifold 8 made of, for example, stainless steel is attached to the opening of the processing chamber 4 with a seal member 10 such as an O-ring interposed therebetween. Alternatively, the processing chamber 4 and the manifold 8 may be integratedly formed in such manner that a cylindrical processing chamber made of quartz has a manifold portion also made of quartz.

The bottom end of the processing chamber 4 is supported by the manifold 8. A wafer boat 12, which is made of quartz, serves as a holding unit mounting thereon a plurality of semiconductor wafers (product wafers) W as target objects in multi-levels, and is vertically-movably inserted into or ejected from the interior of the processing chamber 4 from the underside of the manifold 8. A support 12A of the wafer boat 12 supports, for example, 50 to 150 sheets of wafers W having diameters of 300 mm in multi-levels by almost equal pitches. In order to secure thermal stability of the semiconductor wafers W, dummy wafers DW are held as dummy target objects at the upper and the lower portion of the wafer boat 12, for example.

The wafer boat 12 is mounted on a table 16 with a thermal insulation container 14 made of quartz interposed therebetween, and the table 16 is supported by a rotation shaft 20 passing through a lid 18 made of, for example, stainless steel. The lid 18 opens/closes an opening disposed at the lower end of the manifold 8. The rotation shaft 20 is air-tightly sealed and rotatably supported by, for example, a magnetic fluid seal 22 interposed between the rotation shaft 20 and a through portion of the lid 18. Further, a seal member 24 such as an O-ring is interposed between the peripheral portion of the lid 18 and the lower end of the manifold 8 so that a sealing property of the interior of the processing chamber 4 is maintained.

The rotation shaft 20 is attached to a leading end of an arm 26 supported by an elevation mechanism (not shown) such as a boat elevator, so that the wafer boat 12 and the lid 18 are vertically movable together to be inserted into or ejected from the interior of the processing chamber 4. Alternatively, the table 16 may be fixedly provided on the lid 18 and the wafers W so that the wafers W are processed while the wafer boar 12 is not rotated.

A gas supply system 27 is provided at the manifold 8 to supply various gases into the processing chamber 4. To be specific, the gas supply system 27 includes a nitride gas supply unit 28 supplying a nitride gas, e.g., ammonia (NH₃) gas, a silane gas supply unit 30 supplying a silane gas, e.g., DCS gas, as a film forming gas, a boron-containing gas supply unit 32 supplying a boron-containing gas, e.g., BCl₃ gas, an oxygen-containing gas supply unit 34 supplying an oxygen-containing gas, e.g., O₂ gas, and a purge gas supply unit 36 supplying an inert gas, e.g., N₂ gas.

The nitride gas supply unit 28 has a gas distribution nozzle 38 made of quartz. The gas distribution nozzle 38 passes through the sidewall of the manifold 8 and is bent upward to extend along the inner sidewall of the manifold 8. In the gas distribution nozzle 38, a plurality of gas injection holes 38A spaced apart from each other is formed along the lengthwise direction of the gas distribution nozzle 38, so that the ammonia gas is uniformly injected via the gas injection holes 38A in the horizontal direction.

Similarly, the silane gas supply unit 30 has a gas distribution nozzle 40 made of quartz. The gas distribution nozzle 40 passes through the sidewall of the manifold 8 and is bent upward to extend along the inner sidewall of the manifold 8. In the gas distribution nozzle 40, a plurality of gas injection holes 40A spaced apart from each other is formed along the lengthwise direction of the gas distribution nozzle 40 (see, FIG. 2), so that the DCS gas is uniformly injected via the gas injection holes 40A in the horizontal direction.

Similarly, the boron-containing gas supply unit 32 has a gas distribution nozzle 42 made of quartz. The gas distribution nozzle 40 passes through the sidewall of the manifold 8 and is bent upward to extend along the inner sidewall of the manifold 8. In the gas distribution nozzle 42, a plurality of gas injection holes 42A spaced apart from each other is formed along the lengthwise direction of the gas distribution nozzle 42 (see, FIG. 2), so that the BCl₃ gas is uniformly injected via the gas injection holes 42A in the horizontal direction.

Similarly, the oxygen-containing gas supply unit 34 has a gas distribution nozzle 44 made of quartz. The gas distribution nozzle 44 passes through the sidewall of the manifold 8 and is bent upward to extend along the inner sidewall of the manifold 8. In the gas distribution nozzle 44, a plurality of gas injection holes 44A spaced apart from each other is formed along the lengthwise direction of the gas distribution nozzle 44 (see, FIG. 2), so that the O₂ gas is uniformly injected via the gas injection holes 44A in the horizontal direction.

Similarly, the purge gas supply unit 36 has a gas distribution nozzle 46 passing through the sidewall of the manifold 8. The gas distribution nozzles 38, 40, 42, 44 and 46 are connected to a gas passages 48, 50, 52, 54 and 56, respectively, and opening/closing valves 48A, 50A, 52A, 54A and 56A and flow rate controllers (mass flow controllers) 48B, 50B, 52B, 54B and 56B are provided in the gas passages 48, 50, 52, 54 and 56, respectively. With this configuration, the gas supply system 27 can supply the NH₃ gas, the DCS gas, the BCl₃ gas, the O₂ gas and the N₂ gas into the processing chamber 4 while controlling the flow rate of the gases.

In addition, a nozzle accommodating recess 60 is formed in a portion of the sidewall of the processing chamber 4 in the vertical direction. Further, a thin and long gas exhaust port 62 configured to vacuum-evacuate the inner atmosphere of the processing chamber 4 is formed in an opposite portion to the nozzle accommodating recess 60 in the sidewall of the processing chamber 4 by cutting out the opposite portion of the sidewall of the processing chamber 4 in, for example, a vertical direction. To be specific, the nozzle accommodating recess 60 is formed by cutting out the sidewall of the processing chamber 4 in the vertical direction by a specific width to thereby form a vertically thin and long opening 64 and then by covering the opening 64 with a vertically thin and long partition wall 66, which is made of, e.g., quartz and has a recess-shaped cross section, from the outside of the processing chamber 4 and air-tightly welding the partition wall 66 to the outer wall of the processing chamber 4.

With the configuration discussed above, a portion of the sidewall of the processing chamber 4 is recessed outwardly and the nozzle accommodating recess 60 having a side open to communicate with the interior of the processing chamber 4 is integrally formed with the processing chamber 4. That is, the partition wall 66 is integratedly formed with the processing chamber 4 and the inner space of the partition wall 66 communicates with the interior of the processing chamber 4. The opening 64 is formed to have a height long enough to cover all the wafers W (including the dummy wafers DW) mounted on the wafer boat 12 in the vertical direction. A slit plate having a plurality of slits formed therein may be provided at the opening 64. Further, as shown in FIG. 2, the gas distribution nozzles 38, 40, 42 and 44 are arranged in parallel in the nozzle accommodating recess 60.

Further, a gas exhaust port cover 68, which is made of quartz and has a reverse C-shaped cross section to cover the gas exhaust port 62, is welded to the gas exhaust port 62 facing the opening 64. The gas exhaust port cover 68 extends upwardly along the sidewall of the processing chamber 4 and forms a gas outlet 70 above the processing chamber 4. At the gas outlet 70, a vacuum exhaust system 72 configured to vacuum-evacuate the interior of the processing chamber 4 is provided. To be specific, the vacuum exhaust system 72 includes a gas exhaust passage 74 coupled to the gas outlet 70, and a pressure control valve 76, which can be open/closed and has a controllable opening degree, and a vacuum pump 78 are installed in sequence in the gas exhaust passage 74. In addition, a cylindrical heating unit 80 configured to heat the processing chamber 4 and the wafers W accommodated in the processing chamber 4 is provided to enclose the outer periphery of the processing chamber 4.

Overall operations of the film forming apparatus 2 as described above are controlled by a control unit 82 including, for example, a computer and a computer program controlling the overall operations of the film forming apparatus 2 is stored in a memory 84 such as a flexible disc, a compact disc (CD), a hard disc or a flash memory. To be specific, a start and stop of supply of each of the gases by the opening/closing valves 48A, 50A, 52A, 54A and 56A, a flow rate control of the gases, a process temperature control and a process pressure control are carried out by commands issued from the control unit 82.

The control unit 82 includes a user interface (not shown) connected thereto. The user interface includes a keyboard via which an operator inputs commands for managing the film forming apparatus 2 and a display configured to visualize and display the operational status of the film forming apparatus 2. Further, communications for controlling the film forming apparatus 2 via communication lines may be made with respect to the control unit 82.

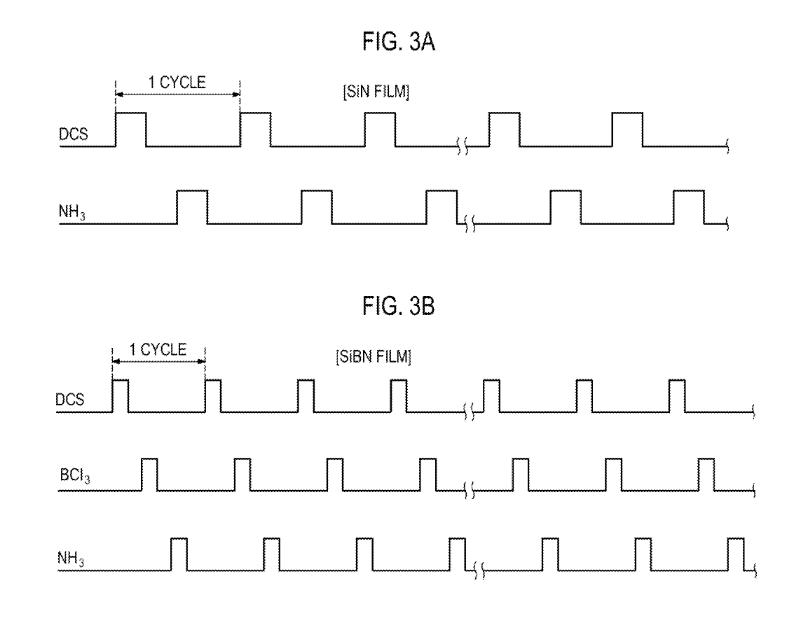

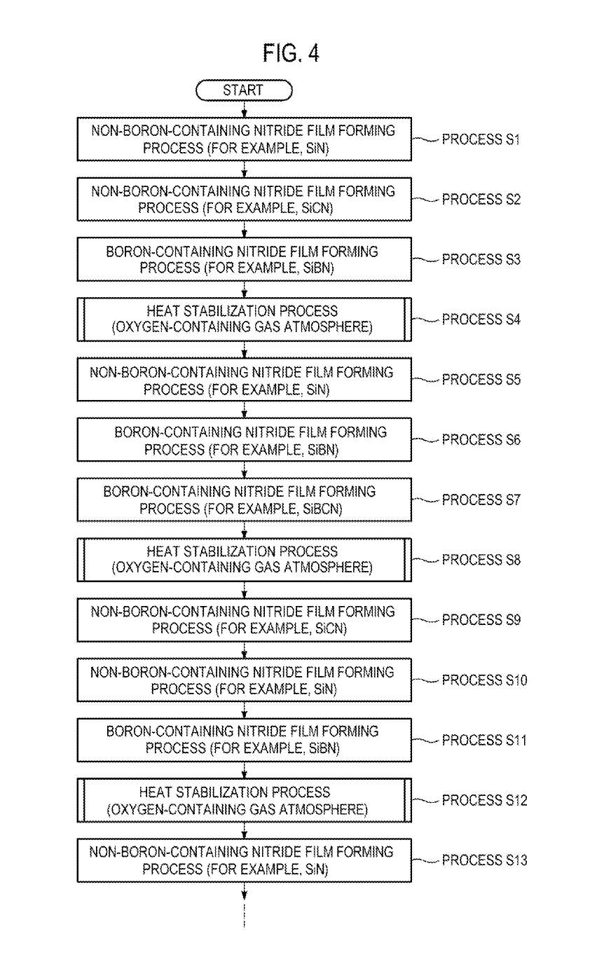

Hereinafter, a stabilization method of a film forming apparatus in accordance with an embodiment of the present disclosure carried out by using the film forming apparatus 2 will be described with reference to FIGS. 3A to 4. According to the stabilization method of a film forming apparatus in which a boron-containing nitride film forming process of forming a boron-containing nitride film or a non-boron-containing nitride film forming process of forming a non-boron-containing nitride film can be selectively performed on a target object to be processed within a vacuum-evacuable processing chamber, when the non-boron-containing nitride film forming process is performed after the boron-containing nitride film forming process is performed, a heat stabilization process for heating the interior of the processing chamber under an oxygen-containing gas atmosphere is performed between the boron-containing nitride film forming process and the non-boron-containing nitride film forming process.

The boron-containing nitride film includes various types of films containing boron, for example, at least one film selected from a group consisting of a SiNB film, a SiBCN film and a BN film. The non-boron-containing nitride film also includes various types of films without containing boron, for example, at least one film selected from a group consisting of a SiN film, a SiCN film and a SiMN film where M denotes a metal. Here, the metal M may include, for example, aluminum (Al), zirconium (Zr), hafnium (Hf), tantalum (Ta), titanium (Ti) and tungsten (W). In the above-described chemical formulas of the nitride films, only types of chemical elements contained in the nitride films are denoted and the number of atoms in the chemical elements are omitted. However, various combinations of the numbers of atoms may be applicable. Further, the oxygen-containing gas may include, for example, at least one gas selected from a group consisting of O₂, O₃, H₂O, N₂O, NO, NO₂ and CO₂.

First, an example of a general film forming method performed by using the film forming apparatus of the present disclosure will be described. In this example, the boron-containing nitride film and the non-boron-containing nitride film are a silicon boron nitride (SiBN) film and a silicon nitride (SiN) film, respectively. FIGS. 3A and 3B are timing charts illustrating supply timings of various gases.

The wafer boat 12, on which a plurality of, for example, 50 to 150 sheets of wafers W having diameters of 300 mm is mounted at a normal temperature, is moved up from the underside of the processing chamber 4 and loaded into the processing chamber 4 of a specific temperature. Then, the opening at the bottom end of the manifold 8 is closed by the lid 18 so that the interior of the processing chamber 4 is sealed.

Thereafter, the processing chamber 4 is vacuum-evacuated to maintain the interior of the processing chamber 4 at a specific process pressure, and an electric power supplied to the heating unit 80 is increased to increase the temperature of the wafers W and maintain the wafers W at a process temperature. When forming a SiN film as a non-boron-containing nitride film, a DCS gas is supplied from the silane gas supply unit 30 and a NH₃ gas is supplied from the nitride gas supply unit 28 as shown in FIG. 3A.

To be specific, the DCS gas is injected in the horizontal direction via the gas injection holes 40A of the gas distribution nozzle 40 and the NH₃ gas is injected in the horizontal direction via the gas injection holes 38A of the gas distribution nozzle 38. As shown in FIG. 3A, a cycle during which the DCS gas and the NH₃ gas are supplied alternately and intermittently is repeated a specific number of times. Between a DCS gas supplying period and a NH₃ gas supplying period (time-adjacent thereto), a purge process for purging residual gases in the processing chamber 4 may be performed. Or, the purge process may be omitted. As shown in FIG. 3A, the time period between two time-adjacent gas supplying processes of the same gas forms one cycle.

By supplying the DCS gas and the NH₃ gas as shown in FIG. 3A, a SiN film is formed on the surface of each of the wafers W, which are held by the wafer boat 12 being rotated, by an atomic layered deposition (ALD) method. After the SiN film is formed, the wafer boat 12 is unloaded and the processed wafers W are taken out from the interior of the processing chamber 4.

On the contrary, when forming a SiBn film as a boron-containing nitride film, the wafer boat 12 on which the wafers are mounted is loaded into the processing chamber 4 as described above. Then, a DCS gas, a BCl₃ gas and a NH₃ gas are supplied from the silane gas supply unit 30, the boron-containing gas supply unit 32 and the nitride gas supply unit 28, respectively, as shown in FIG. 3B.

To be specific, the DCS gas, the BCl₃ gas and the NH₃ gas are injected in the horizontal direction via the gas injection holes 40A of the gas distribution nozzle 40, the gas injection holes 42A of the gas distribution nozzle 42 and the gas injection holes 38A of the gas distribution nozzle 38, respectively. As shown in FIG. 3B, a cycle during which the DCS gas, the BCl₃ gas and the NH₃ gas in this sequence are supplied alternately and intermittently is repeated a specific number of times.

Between a DCS gas supplying period and a BCl₃ gas supplying period (time-adjacent thereto) and between a DCS gas supplying period and a NH₃ gas supplying period (time-adjacent thereto), a purge process for purging residual gases in the processing chamber 4 may be performed. Or, the purge process may be omitted. As shown in FIG. 3B, a time period between two time-adjacent gas supplying processes of the same gas forms one cycle. By supplying the DCS gas, the BCl₃ gas and the NH₃ gas as shown in FIG. 3B, a SiBN film is formed as a stacked structure on the surface of each of the wafers W, which are held by the wafer boat 12 being rotated, by an atomic layered deposition (ALD) method.

The gas supplying timings as shown in FIGS. 3A to 3B are merely an example, and gas supplying timings are not limited thereto. Further, though the SiN film and the SiBN film are formed as a non-boron-containing nitride film and a boron-containing nitride film, respectively, in the above-described example, various nitride films as discussed above may be formed as a boron-containing nitride film and a non-boron-containing nitride film. For example, a SiBCN film containing carbon as an impurity may be formed as a boron-containing nitride film. Further, when doping with elements not being used in forming the SiN film and the SiBN film as impurities, a gas supply unit configured to supply a doping gas containing the doping elements may be provided to the film forming apparatus 2 shown in FIG. 1.

In the above-described manner, both the boron-containing nitride film forming process and the non-boron-containing nitride film forming process are performed using the film forming apparatus 2. According to need, the boron-containing nitride film forming process and the non-boron-containing nitride film forming process may be performed selectively. As described above, in the stabilization method of the present disclosure, when a non-boron-containing nitride film forming process is performed after a boron-containing nitride film forming process is performed, a heat stabilization process for heating the interior of the processing chamber under an oxygen-containing gas atmosphere is performed between the boron-containing nitride film forming process and the non-boron-containing nitride film forming process.

The above-described features will be described with reference to FIG. 4. FIG. 4 is a flowchart for explaining a stabilization method of a film forming apparatus in accordance with an embodiment of the present disclosure, in which a series of processes performed in the film forming apparatus, is illustrated. The processes are performed in sequence shown in FIG. 4 by using the film forming apparatus 2 shown in FIG. 1. As described above, in the method of the present disclosure, when a non-boron-containing nitride film forming process is performed after a boron-containing nitride film forming process is performed, a heat stabilization process is performed between the boron-containing nitride film forming process and the non-boron-containing nitride film forming process.

By way of example only, processes S1 to S13 are shown in FIG. 4, but when necessary, such processes may be also performed after the process S13. In FIG. 4, non-boron-containing nitride film forming processes are performed in the processes S1, S2, S5, S9, S10 and S13, and boron-containing nitride film forming processes are performed in the processes S3, S6, S7 and S11. Further, heat stabilization processes are performed in the processes S4, S8 and S12 between the non-boron-containing nitride film forming processes and the boron-containing nitride film forming processes, i.e., right before the non-boron-containing nitride film forming processes when the process type is changed from the boron-containing nitride film forming processes to the non-boron-containing nitride film forming processes.

By performing the heat stabilization processes as shown in FIG. 4, the interior of the processing chamber 4 gets stabilized after the boron-containing nitride film forming processes, to thereby prevent boron from exerting a bad influence on a subsequent non-boron-containing nitride film forming processes and improve reproducibility of the film forming processes. In order to perform the heat stabilization processes, semiconductor wafers W, on which nitride films are formed during the boron-containing nitride film processes, e.g., the processes S3, S7 and S11, performed right before the stabilization processes, are unloaded and taken out from the processing chamber 4. Then, the stabilization processes are performed under a state where the wafer boat 12 in an empty state of unloading the product wafers W is loaded into the processing chamber 4 again and the processing chamber 4 is sealed. During the heat stabilization processes, the wafer boat 12 is mounted on the thermal insulation container 14 and the dummy wafers DW, for example, which have been permanently held at the upper and the lower portions of the wafer boat 12, are still kept to be held at the upper and the lower portions of the wafer boat 12.

In the heat stabilization processes, the interior of the processing chamber 4 is heated for a specific time period under an oxygen-containing gas atmosphere, e.g., an O₂ gas atmosphere, while an O₂ gas is injected via the gas injection holes 44A of the gas distribution nozzle 44.

By performing the heat stabilization processes, boron (B) atoms forming “B—N bonds” in boron-containing nitride films, which are unnecessarily deposited to the inner wall of the processing chamber 4 made of quartz, the surface of the wafer boat 12, the surface of the thermal insulation container 14 and the dummy wafers DW made of silicon substrates, react with oxygen (O) atoms so that the “B—N bonds” are replaced with stabilized “B—O bonds” without having nitrogen (N) atoms.

The boron-containing nitride films unnecessarily deposited on the inner wall of the processing chamber 4 and the like are stabilized, i.e., boron atoms in the boron-containing nitride films are stabilized by forming the “B—O bonds” through the heat stabilization processes as described above. Thus, boron atoms do not have catalytic actions when the non-boron-containing nitride film forming processes, e.g., the processes S5, S9 and S13, are performed right after the heat stabilization processes. Namely, since boron atoms do not have catalytic actions, boron atoms do not exert influence on the non-boron-containing nitride films such as SiN films. Thus, the desired film thicknesses of the non-boron-containing nitride films can be obtained and in-plane uniformities of the film thicknesses can be kept to be high, thereby improving the reproducibility of the film forming processes.

Regarding process conditions of the heat stabilization process, a process temperature ranges from about 500 degrees C. to about 800 degrees C. and a process pressure ranges from about 1 Torr to about 730 Torr (a normal temperature). In some embodiments, the process temperature may range from about 600 degrees C. to about 700 degrees C. and the process pressure may range from about 100 Torr to about 600 Torr. If the process temperature is below 500 degrees C., it is hard to form the “B—O bonds”. The process temperature may be set to above 800 degrees C. However, considering process temperatures in the processes performed before and after the heat stabilization processes, it is undesirable to set the process temperature of the heat stabilization processes to above 800 degrees C., because it takes a long time to increase the temperature of the processing chamber 4 and the throughput is lowered.

If the process pressure is below 1 Torr, it is hard to form the “B—O bonds” because the concentration of the oxygen-containing gas becomes too low. Though there does not exist the upper limit of the process pressure, it is undesirable to set the process pressure to above 760 Torr, because configuration of the film forming apparatus 2 needs to be changed in order to set the process pressure to above 760 Torr.

In addition, a process time ranges from about 5 minutes to about 60 minutes. In some embodiments, the process time may range from about 10 minutes to about 30 minutes. If the process time is set to be shorter than 5 minutes, the “B—O bonds” are not formed sufficiently. It is also undesirable to set the process time to be longer than 60 minutes because the throughput is lowered. In addition, a flow rate of the O₂ gas ranges from about 3.0 slm (standard liter per minute) to about 5.0 slm. If the flow rate of the O₂ gas is below 3.0 slm, the “B—O bonds” are not formed sufficiently. It is also undesirable to set the flow rate of the O₂ gas to above 5.0 slm because an unnecessarily large amount of the O₂ gas is consumed.

As described above, according the stabilization method of the film forming apparatus 2 in which a boron-containing nitride film forming process or a non-boron-containing nitride film forming process can be selectively performed on the target object W within the vacuum-evacuable processing chamber 4, when the non-boron-containing nitride film forming process is performed after the boron-containing nitride film forming process is performed, a heat stabilization process for heating the interior of the processing chamber 4 under an oxygen-containing gas atmosphere is performed between the boron-containing nitride film forming process and the non-boron-containing nitride film forming process. Accordingly, the processing chamber 4 gets stabilized after the boron-containing nitride film forming process to thereby prevent boron from exerting a bad influence on the subsequent non-boron-containing nitride film forming process and improve reproducibility of the film forming processes.

### <Evaluation of the Stabilization Method of the Present Disclosure>

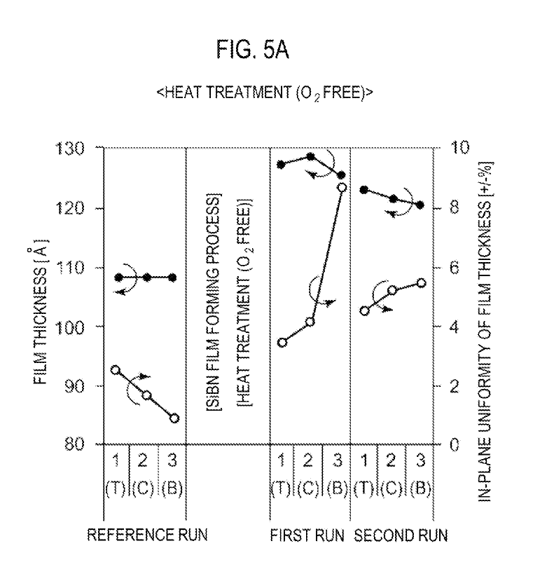

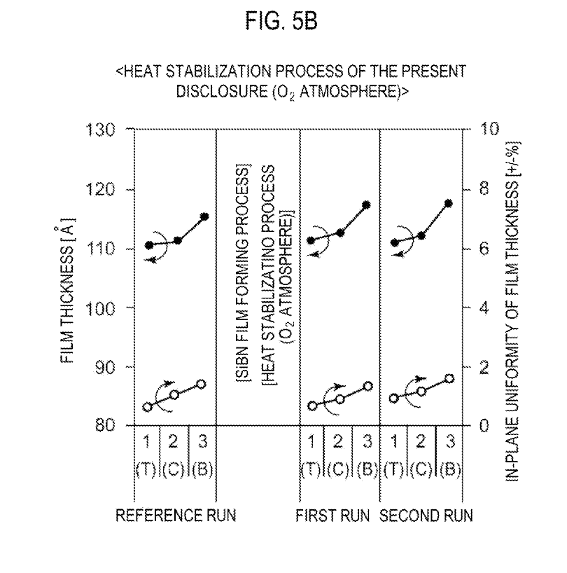

Hereinafter, evaluation results of the stabilization method of the present disclosure will be described with reference to FIGS. 5A and 5B. FIGS. 5A and 5B are graphs illustrating evaluation results of the stabilization method of the film forming apparatus in accordance with an embodiment of the present disclosure. FIG. 5A is a graph obtained by performing a heat treatment under an oxygen-containing gas free state (no O₂ gas state), and FIG. 5B is a graph obtained by performing a heat treatment under an oxygen-containing gas state (O₂ gas atmosphere state), i.e., by performing a heat stabilization process of the present disclosure.

In both cases shown in FIGS. 5A and 5B, film forming processes were performed by using a vertical film forming apparatus capable of simultaneously processing a plurality of semiconductor wafers, e.g., by using the film forming apparatus shown in FIG. 1. To be specific, a reference run was first performed to form a pure silicon nitride (SiN) film under a state where the inner wall of the film forming apparatus is not contaminated with boron. Semiconductor wafers were then replaced and a SiBN film was formed as a boron-containing silicon nitride film. Thereafter, the wafer boat was unloaded from the processing chamber and the wafers were taken leaving the wafer boat in an empty state. In the empty state, the dummy wafers DW were still held by the wafer boat. Then, the wafer boat in the empty state was loaded into the processing chamber again and the processing chamber was sealed.

Thereafter, in case of FIG. 5A, a heat treatment without supplying an O₂ gas was performed for 10 minutes at a temperature of 630 degrees C. On the contrary, in FIG. 5B, a heat treatment (heat stabilization process) was performed for 10 minutes at a temperature of 630 degrees C. while supplying an O₂ gas with a flow rate of 5.0 slm to keep the interior of the processing chamber 4 under an oxygen atmosphere. In both cases, the process pressure was set to 120 Torr. Then, in both cases, a first run and a second run were sequentially performed to form pure silicon nitride (SiN) films. Semiconductor wafers were replaced for each of the runs (film forming processes). FIGS. 5A and 5B illustrate film thicknesses and in-plane uniformities of the film thicknesses.

In FIGS. 5A and 5B, black circles “” denote the film thicknesses and white circles “o” denote the in-plane uniformities of the film thicknesses, while the left-side vertical axis and the right-side vertical axis are scaled by the film thicknesses and the in-plane uniformities of the film thicknesses, respectively. Also, the wafer boat supporting the semiconductor wafers is vertically divided into three regions. In FIGS. 5A and 5B, the three regions are denoted by three numbers in such a manner that the top most region, the center region and the bottom most region are denoted by “1”, “2” and “3”, respectively. Further, “T”, “C” and “B” shown in 5A and 5B denote “top”, “center” and “bottom”, respectively.

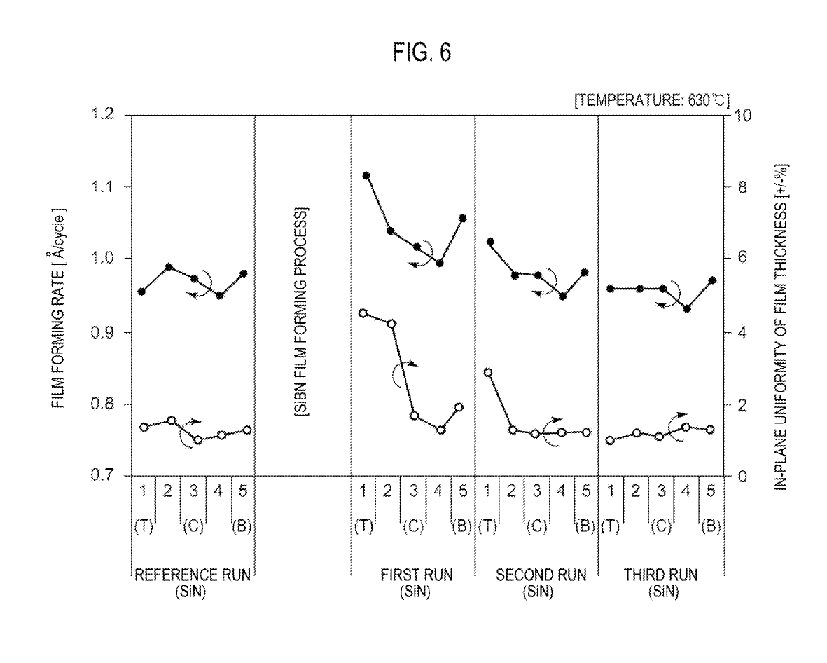

As shown in FIG. 5A, by simply performing a heat treatment on the processing chamber without supplying O₂ gas after forming the SiBN film as a boron-containing nitride film, the SiN films generated on the first and the second run have film thicknesses thicker than the film thickness of the SiN film generated at the reference run and the in-plane uniformities on the first and the second run deteriorated. That is, FIG. 5A shows substantially the same result as that of the conventional film forming process as discussed above with reference to FIG. 6.

On the contrary, in case of a method of the present disclosure as shown in FIG. 5B, heat treatment under an O₂ gas atmosphere, i.e., the heat stabilization process, was performed on the processing chamber after forming the SiBN film. FIG. 5B shows that film thicknesses and in-plane uniformities at the first and the second run are substantially the same as those at the reference run throughout the entire regions T, C and B and that reproducibility of the film forming process is kept well.

By way of example only, the film forming process is performed using an ALD method, in which a plurality of film forming gases are alternately supplied into the processing chamber, in the above-described embodiments. However, the film forming process is not limited thereto. The present disclosure may also be applied to a chemical vapor deposition (CVD) method in which a plurality of film forming gases are simultaneously supplied into the processing chamber.

By way of example only, the film forming process is performed using thermal energy in the above-described embodiments. However, the film forming process is not limited thereto. The present disclosure may also be applied to a film forming method and apparatus using plasma energy, in which a plasma generation unit is provided in the processing chamber and film forming gases are activated by plasma.

By way of example only, the film forming process is performed on a semiconductor wafer, as a target object to be processed, in the above-described embodiments. The semiconductor wafer includes silicon substrates and compound semiconductor substrates such as GaAs, SiC and GaN substrates. However, the target object is not limited the above-described substrate. The present disclosure may be also applied to glass substrates used in liquid crystal displays or ceramic substrates.

According to the present disclosure, in a stabilization method of a film forming apparatus, which is configured to selectively perform a boron-containing nitride film forming process or a non-boron-containing nitride film forming process on at least one target object to be processed in a vacuum-evacuable processing chamber, when the non-boron-containing nitride film forming process is performed after the boron-containing nitride film forming process, a heat stabilization process to heat the interior of the processing chamber under an oxygen-containing gas atmosphere is performed between the boron-containing nitride film forming process and the non-boron-containing nitride film forming process. Accordingly, the interior of the processing chamber gets stabilized after the boron-containing nitride film forming processes, to thereby prevent boron from exerting a bad influence on subsequent non-boron-containing nitride film forming processes and improve reproducibility of the film forming processes.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method for stabilizing a film forming apparatus which can selectively perform a boron-containing nitride film forming process or a non-boron-containing nitride film forming process on at least one target object to be processed in a vacuum-evacuable processing chamber, the method comprising:
performing a heat stabilization process to heat the interior of the processing chamber under an oxygen-containing gas atmosphere, between the boron-containing nitride film forming process and the non-boron-containing nitride film forming process when the non-boron-containing nitride film forming process is performed after the boron-containing nitride film forming process.

2. The method of claim 1, wherein a holding unit configured to hold the target object in the processing chamber is accommodated in the processing chamber.

3. The method of claim 2, wherein a dummy target object is held on the holding unit.

4. The method of claim 1, wherein the oxygen-containing gas includes at least one gas selected from a group consisting essentially of O₂, O₃, H₂O, N₂O, NO, NO₂ and CO₂.

5. The method of claim 1, wherein the boron-containing nitride film includes at least one film selected from a group consisting essentially of a SiNB film, a SiBCN film and a BN film.

6. The method of claim 1, wherein the non-boron-containing nitride film includes at least one film selected from a group consisting essentially of a SiN film, a SiCN film and a SiMN film where M denotes a metal.

7. The method of claim 1, wherein a process temperature of the heat stabilization process ranges from 500 degrees C. to 800 degrees C.

8. A film forming apparatus configured to form thin films on at least one target object to be processed, the apparatus comprising:
a gas-evacuable processing chamber including a vertical and cylindrical shape;
a holding unit configured to hold the target object in multi-levels and to be inserted into and ejected from the interior of the processing chamber;
a heating unit installed around the outer periphery of the processing chamber;
a gas supply system configured to supply a plurality of gases into the processing chamber; and
a control unit configured to control the film forming apparatus to perform the stabilization method as set forth in claim 1.

9. The film forming apparatus of claim 8, wherein the gas supply system comprises:
a silane gas supply unit configured to supply a silane gas into the processing chamber;
a nitride gas supply unit configured to supply a nitride gas into the processing chamber;
a boron-containing gas supply unit configured to supply a boron-containing gas into the processing chamber; and
an oxygen-containing gas supply unit configured to supply an oxygen-containing gas into the processing chamber.
